(19) United States
(12) Patent Application Publication
(10) Pub. No.: US 2023/0317560 A1
(43) Pub. Date: Oct. 5, 2023

(54) POWER SEMICONDUCTOR MODULE, SYSTEM INCLUDING A POWER SEMICONDUCTOR MODULE AND A COOLER AND METHOD FOR FABRICATING A SYSTEM

(71) Applicant: Infineon Technologies AG, Neubiberg (DE)

(72) Inventor: Andre Uhlemann, Warstein (DE)

(21) Appl. No.: 18/122,817

(22) Filed: Mar. 17, 2023

(30) Foreign Application Priority Data
Mar. 31, 2022 (DE) 102022107649.0

(51) Int. Cl. H01L 23/473; H01L 23/049; H01L 23/31; H01L 23/373; H01L 25/065

(52) U.S. Cl. CPC H01L 23/473; H01L 23/049; H01L 23/315; H01L 23/3735; H01L 25/0655

(57) ABSTRACT

A power semiconductor module includes a carrier comprising a first side and an opposite second side, a power semiconductor die arranged at the first side of the carrier, and a housing arranged at least partially on the second side of the carrier and forming a joining site for a cooler on the second side. The joining site completely surrounds an inner portion of the second side of the carrier. The inner portion is configured to be in direct contact with a cooling fluid within the cooler.

### TECHNICAL FIELD

This disclosure relates in general to a power semiconductor module, to a system comprising a power semiconductor module and a cooler, as well as to a method for fabricating such a system.

### BACKGROUND

Power semiconductor modules may generate a considerable amount of heat during operation, such that it may be necessary to provide dedicated cooling means for dissipating this heat. One particularly efficient heat dissipation scheme is the so called “direct liquid cooling” scheme, wherein a part of the power semiconductor module, e.g. a baseplate, is in direct contact with a cooling fluid. The direct liquid cooling scheme does not require any thermal interface material layer arranged between the power semiconductor module and the cooler. Such a layer would increase the thermal resistance of the heat dissipation path. Sealing elements like, for example, sealing rings may be used to provide a watertight seal between the power semiconductor module and the cooler. However, such sealing elements may deteriorate over the lifetime of the power semiconductor module, which may result in a critical fail of the seal. Furthermore, the use of such sealing elements in a power semiconductor module may be comparatively costly. Improved power semiconductor modules, improved systems comprising a power semiconductor module and a cooler and improved methods for fabricating such systems may help to solve these and other problems.

The problem on which the invention is based is solved by the features of the independent claims. Further advantageous examples are described in the dependent claims.

### SUMMARY

Various aspects pertain to a power semiconductor module, comprising: a carrier comprising a first side and an opposite second side, a power semiconductor die arranged at the first side of the carrier, and a housing arranged at least partially on the second side of the carrier and forming a joining site for a cooler on the second side, wherein the joining site completely surrounds an inner portion of the second side of the carrier, wherein the inner portion is configured to be in direct contact with a cooling fluid within the cooler.

Various aspects pertain to a power semiconductor module, comprising: a carrier comprising a first side and an opposite second side, and a power semiconductor die arranged on the first side of the carrier, wherein a joining site for a cooler on the second side of the carrier comprises a roughened surface texture and/or a plurality of micro holes, the joining site completely surrounding an inner portion of the second side of the carrier, wherein the inner portion is configured to be in direct contact with a cooling fluid within the cooler.

Various aspects pertain to a system, comprising: a power semiconductor module, comprising: a carrier comprising a first side and an opposite second side, and a power semiconductor die arranged on the first side of the carrier; and a cooler arranged on the second side of the carrier, such that the carrier and the cooler form a fluid channel, wherein the power semiconductor module and the cooler are joined by a thermoplastic bond.

Various aspects pertain to a method for fabricating a system, the method comprising: providing a power semiconductor module, comprising: a carrier comprising a first side and an opposite second side, and a power semiconductor die arranged on the first side of the carrier; arranging a cooler on the second side of the carrier such that the carrier and the cooler form a fluid channel; and joining the power semiconductor module and the cooler with a thermoplastic bond.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIGS. 1A and 1B show a sectional view (FIG. 1A) and a plan view (FIG. 1B) of an exemplary power semiconductor module comprising a housing, wherein the housing provides a joining site for a cooler.

FIG. 2 shows a sectional view of an exemplary system comprising a power semiconductor module and a cooler joined to the power semiconductor module via a thermoplastic bond.

FIG. 3 shows a sectional view of a further exemplary power semiconductor module, wherein a carrier of the module comprises a joining site comprising a roughened surface texture and/or a plurality of micro holes.

FIG. 4 shows a sectional view of a further exemplary system comprising a power semiconductor module and a cooler.

FIG. 5 shows a sectional view of a further exemplary system comprising a plastic interface for joining a power semiconductor module and a cooler.

FIG. 6 shows a sectional view of a further exemplary system, wherein the cooler comprises turbulence generating structures.

FIG. 7 is a flow chart of an exemplary method for fabricating a system comprising a power semiconductor module and a cooler.

### DETAILED DESCRIPTION

In the following detailed description, directional terminology, such as “top”, “bottom”, “left”, “right”, “upper”, “lower” etc. is used with reference to the orientation of the Figure(s) being described. Because components of the disclosure can be positioned in a number of different orientations, the directional terminology is used for purposes of illustration only.

In addition, while a particular feature or aspect of an example may be disclosed with respect to only one of several implementations, such a feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or in the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless of whether they are in direct physical or electrical contact with each other or not; intervening elements or layers may be provided between the “bonded”, “attached”, or “connected” elements. Also, the term “exemplary” is merely meant as an example, rather than the best or optimal.

An efficient power semiconductor module, an efficient system comprising a power semiconductor module and a cooler and an efficient method for fabricating such a system may for example reduce material consumption and/or ohmic losses and/or chemical waste and may thus enable energy and/or resource savings. Improved power semiconductor modules, improved systems and improved methods for fabricating a system, as specified in this description, may thus at least indirectly contribute to green technology solutions, i.e. climate-friendly solutions providing a mitigation of energy and/or resource use.

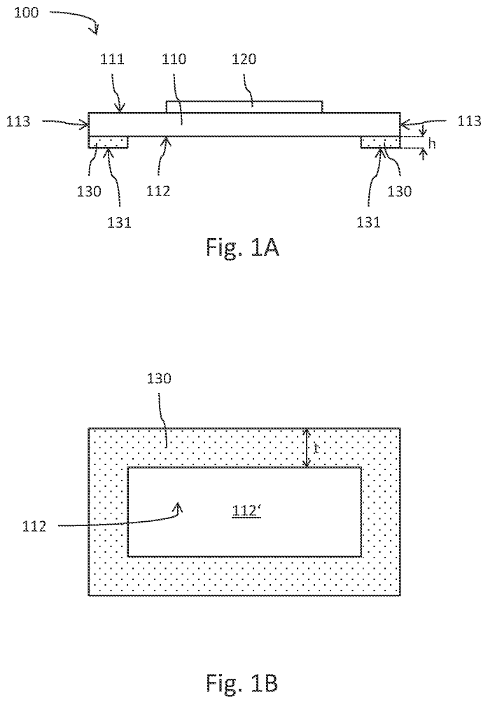

FIGS. 1A and 1B show an exemplary power semiconductor module 100 comprising a carrier 110, a power semiconductor die 120 and a housing 130. FIG. 1A shows a sectional view of the power semiconductor module 100 and FIG. 1B shows a plan view onto a second side 112 of the carrier 110 of the power semiconductor module 100.

The carrier 110 comprises a first side 111 and the second side 112, wherein the second side 112 is opposite to the first side 111. The carrier 110 may also comprise lateral sides 113 connecting the first and second sides 111, 112.

According to an example, the carrier 110 comprises a single part, e.g. a power electronic substrate or a baseplate. Such a power electronic substrate may comprise two conductive layers separated by an insulating layer. Such a power electronic substrate may for example be a substrate of the type DCB (direct copper bonded), DAB (direct aluminum bonded), AMB (active metal brazed), etc. A baseplate may for example be or comprise a metal sheet. A baseplate may for example comprise or consist of Cu or Al or AlSiC. The baseplate may for example comprise a nickel plating.

According to another example, the carrier 110 is a compound of at least two parts, e.g. a compound of a power electronic substrate and a lid part for a fluid channel. The lid part may for example be or comprise a baseplate. The power semiconductor die 120 may be arranged on the power electronic substrate and the power electronic substrate may in turn be arranged on the lid part. The power electronic substrate may for example be soldered or glued to the lid part.

The power semiconductor die 120 is arranged at the first side 111 of the carrier 110. The power semiconductor die 120 may for example be soldered or glued to the carrier 110. The power semiconductor die 120 may comprise a first electrode arranged on the lower side of the power semiconductor die 120, wherein the lower side faces the carrier 110. The electrode on the lower side may be electrically coupled to at least a part of the carrier 110, e.g. to a power electronic substrate of the carrier 110. The power semiconductor die 120 may comprise a second electrode arranged on the upper side of the power semiconductor die 120, wherein the upper side faces away from the carrier 110.

The power semiconductor die 120 may be configured to operate with a high electrical current, e.g. a current of 1 A or more, and/or a high voltage, e.g. a voltage of 1 kV or more. The power semiconductor die 120 may for example be a MOSFET or an IGBT.

According to an example, the power semiconductor module 100 comprises one or more further power semiconductor dies 120 which may also be arranged on the first side 111 of the carrier 110. The power semiconductor dies 120 may be coupled together to provide any suitable electrical circuit, e.g. a converter circuit, an inverter circuit, a half bridge circuit, etc.

The housing 130 is arranged at least partially on the second side 112 of the carrier 110. Furthermore, the housing 130 forms a joining site for a cooler on the second side 112. In other words, the power semiconductor module 100 may be joined to a cooler at the joining site provided by the housing 130.

The housing 130 may in particular comprise a lower side 131 facing away from the second side 112 of the carrier 110. The lower side 131 may be configured as the joining site for the cooler. That is, the power semiconductor module 100 may be joined to a cooler such that the lower side 131 of the housing 130 is in direct contact with the cooler.

The housing 130 may comprise any suitable material or material composition. The housing may for example comprise a mold material, a cast material, a polymer, a plastic, a dispensed material, etc. The housing 130 may be configured to be heated when the power semiconductor module 100 is joined to a cooler. Heating up the housing 130 may at least partially melt the material of the housing 130. A cooler may be pressed onto or into the molten material. Once the molten material has hardened, a tight joint in the form of a thermoplastic bond between the power semiconductor module 100 and the cooler has formed. The joint may in particular seal a fluid channel provided by the cooler. Heating up the material of the housing 130 may comprise pressing a heated cooler onto the housing 130 (the cooler may for example be heated in an oven, over a Bunsen burner, a hot plate, etc.). This method of fabricating a thermoplastic bond between the housing 130 and the cooler may be referred to as a “heat staking process”.

As shown in FIG. 1B, the joining site (or the housing 130) completely surrounds an inner portion 112′ of the second side 112 of the carrier 110. The inner portion 112′ is configured to be in direct contact with a cooling fluid within a cooler, when the power semiconductor module 100 is joined to a cooler. The carrier 110 may in particular be configured to be arranged over an opening of the cooler such that when the opening is sealed by the carrier 110 and the housing 130, a fluid channel is provided. A cooling fluid within the fluid channel may come into direct contact with the second side 112 of the carrier 110 (in particular, the inner portion 112′ of the second side 112).

In the example shown in FIGS. 1A and 1B, the housing 130 is arranged solely on the second side 112 of the carrier 110. However, it is also possible that the housing additionally at least partially covers one or more of the lateral sides 113 of the carrier 110. Additionally or alternatively, it is possible that the housing at least partially covers the first side 111 of the carrier 110. The housing 130 may for example cover the power semiconductor die 120 or the housing may provide a frame on the first side 111, wherein the power semiconductor die 120 is arranged within an interior volume surrounded by the frame. In the latter case, the interior volume may be at least partially filled with an encapsulant (e.g. a polymer, a gel, a mold, etc.) covering the power semiconductor die 120.

The housing 130 or the part of the housing 130 on the second side 112 of the carrier 110 may have any suitable dimensions. For example, the housing 130 may have a height h (compare FIG. 1A) in the range of about 1 mm to about 20 mm. The lower limit of this range may also be about 3 mm, about 5 mm, about 8 mm or about 10 mm and the upper limit may also be about 18 mm, about 15 mm, or about 12 mm. The housing 130 may for example have a thickness t (compare FIG. 1B) in the range of about 1 mm to about 20 mm. The lower limit of this range may also be about 3 mm, about 5 mm, about 8 mm or about 10 mm and the upper limit may also be about 18 mm, about 15 mm, or about 12 mm.

According to an example, the inner portion 112′ of the second side 112 of the carrier 110 comprises a plurality of cooling structures (not shown in FIGS. 1A and 1B). The cooling structures may be configured to increase the surface area of the inner portion 112′ and may for example comprise pin fins, ribbons, etc. The cooling structures may be a contiguous part of the carrier 110 or the cooling structures may be coupled to the carrier 110.

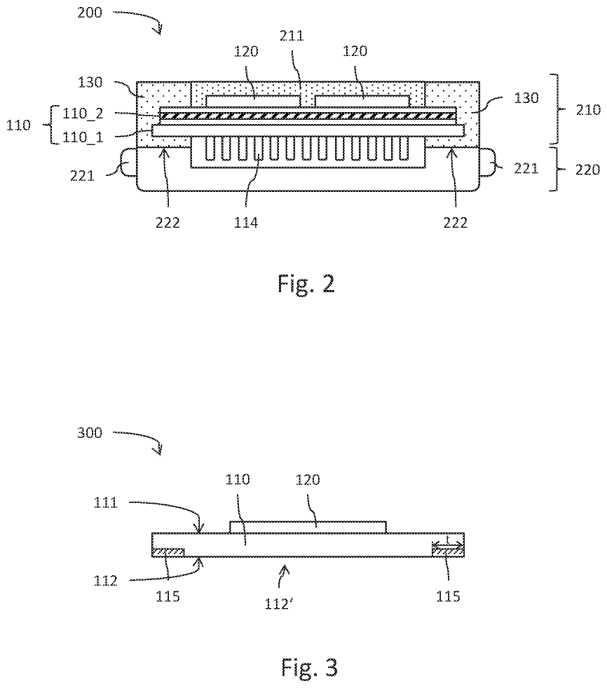

FIG. 2 shows a system 200 comprising a power semiconductor module 210 and a cooler 220. The power semiconductor module 210 shown in FIG. 2 may for example be similar or identical to the power semiconductor module 100 shown in FIGS. 1A and 1B.

As shown in FIG. 2, the cooler 220 is joined to the power semiconductor module 210 at the joining site provided by the housing 130. As mentioned further above, at least a part of the housing 130 has been molten in order to provide a thermoplastic bond joining the cooler 220 to the power semiconductor module 210. This may in particular mean that no additional fastening elements like screws, rivets or clamps may be necessary to fasten the cooler 220 to the power semiconductor module 210. This may also mean that the system 200 may comprise a burr or a similar alteration in the housing 130 where the material of the housing 130 has been molten. Furthermore, it may not be necessary to provide a sealing ring that seals the interface between the power semiconductor module 210 and the cooler 220 because the interface is sealed by the hardened material of the housing 130 (i.e. the thermoplastic bond fabricated by a heat staking process).

According to an example, the power semiconductor module 210 comprises a compound carrier 110 comprising a baseplate 110_1 and one or more power electronic substrates 110_2 arranged on the baseplate 110_1. The baseplate 110_1 and the power electronic substrate 110_2 may have the same dimensions or different dimensions (the latter case is shown in FIG. 2). The housing 130 may be arranged solely on the baseplate 110_1 (in particular, on the lower side of the baseplate 110_1) or the housing 130 may be arranged both on the baseplate 110_1 and on the power electronic substrate 110_2 (the latter case is shown in FIG. 2).

In the example shown in FIG. 2, the system 200 comprises more than one power semiconductor die 120. The power semiconductor dies 120 may for example be arranged laterally next to each other on the carrier 110. All power semiconductor dies 120 may e.g. be arranged on the same power electronic substrate 110_2 or the system 200 may comprise more than one power electronic substrates 110_2, wherein individual power semiconductor dies 120 are arranged on different ones of the power electronic substrates 110_2. The more than one power electronic substrates 110_2 may be arranged laterally next to each other on a single baseplate 110_1. However, it is also possible that the system 200 comprises more than one baseplate 110_1, wherein the baseplates 110_1 can be arranged over different openings of the cooler 220.

According to an example, the carrier 110 (or the baseplate 110_1) comprises a plurality of cooling structures 114 extending into the fluid channel. The cooling structures 114 may be contiguous parts of the carrier 110 or the cooling structures 114 may be joined to the carrier 110, e.g. by plugging, screwing, gluing or soldering.

The exemplary power semiconductor module 210 shown in FIG. 2 comprises an encapsulation 211 encapsulating the power semiconductor dies 120. The encapsulation 211 may be different from the housing 130, for example because the encapsulation 211 comprises a different material or material composition and/or because the encapsulation 211 is fabricated in a different fabrication step than the housing 130. It is however also possible that the housing 130 and the encapsulation 211 are one integral part fabricated in the same fabrication step.

The cooler 220 may for example comprise or consist of a metal or metal alloy. According to an example, the cooler 220 comprises or consists of Al. The cooler 220 may be a single piece or the cooler 220 may be a compound of several parts. The cooler 220 may e.g. comprise a first inlet/outlet 221 and a second inlet/outlet 221 which may e.g. be arranged on opposite lateral sides of the cooler 220. The cooler 220 may be configured to be operable with any suitable cooling fluid, e.g. water.

According to an example, an upper surface 222 of the cooler 220, wherein the upper surface 222 is configured to be joined to the power semiconductor module 210 at the joining site provided by the housing 130, may comprise a roughened surface texture and/or a plurality of micro holes and/or a ridge and/or a furrow in order to improve the adhesion between the housing 130 and the cooler 220.

FIG. 3 shows a power semiconductor module 300 comprising a carrier 110 and a power semiconductor die 120 arranged on the carrier 110. The power semiconductor module 300 shown in FIG. 3 may be similar to the power semiconductor module 100 shown in FIGS. 1A and 1B, except for the differences described in the following. The power semiconductor module 300 may comprise further parts not shown in FIG. 3, e.g. an encapsulant encapsulating the power semiconductor die 120.

The power semiconductor module 300 shown in FIG. 3 does not necessarily comprise the joining site provided by the housing 130 as does the power semiconductor module 100 shown in FIGS. 1A and 1B. Instead or in addition, the carrier 110 itself of the power semiconductor module 300 comprises a joining site 115 for a cooler. While the joining site of the power semiconductor module 100 may be provided by a plastic part or a polymer part or a molded part, the joining site 115 of the power semiconductor module 300 may be provided by a metal part.

The joining site 115 is arranged on the second side 112 of the carrier 110. The joining site 115 comprises a roughened surface texture and/or a plurality of micro holes and/or a ridge and/or a furrow. In particular, the joining site 115 may have a greater surface roughness than the inner portion 112′ of the second side 112 of the carrier 110. The surface roughness may e.g. be defined by the profile roughness parameter Ra. The surface roughness parameter Ra of the joining site 115 may e.g. be two times, three times, four times, five times, ten times or even more greater than the surface roughness parameter Ra of the inner portion 112′ of the second side 112.

According to an example, the roughened surface texture and/or the micro holes and/or the ridge and/or the furrow of the joining site 115 are structures fabricated using a laser and/or an etching process and/or a stamping process and/or a mechanical treatment like polishing or grinding. The micro holes may extend only partially through the carrier 110 or the micro holes may extend fully through the carrier 110. The micro holes may for example have a diameter of 700 μm or less, or 100 μm or less, or 50 μm or less, or 20 μm or less, or 10 μm or less, or 5 μm or less.

The joining site 115 completely surrounds the inner portion 112′ of the second side 112 of the carrier 110 (similar to the housing 130 completely surrounding the inner portion 112′, as shown in FIG. 1B). The inner portion 112′ is configured to be in direct contact with a cooling fluid within a cooler when the power semiconductor module 300 is joined to the cooler.

The joining site 115 may be configured to be brought into contact with a polymer part or plastic part of a cooler and the joining site 115 may be configured to be heated up which in turn will melt the polymer part or plastic part of the cooler. After hardening of the molten material, the cooler is firmly affixed to the carrier 110 at the joining site 115 via a thermoplastic bond. However, in contrast to the power semiconductor module 100 shown in FIGS. 1A and 1B, the material of the cooler and not the material of a housing of the power semiconductor module 300 shown in FIG. 3 is used to fabricate the thermoplastic bond.

According to an example, the carrier 110 comprises an adhesion promotion layer, at least in the joining site 115, wherein the adhesion promotion layer has a different reflective factor than the rest of the second side 112. The adhesion promotion layer may for example comprise or consist of a coating, e.g. an inorganic coating, covering the second side 112 or covering at least the joining site 115. The joining site 115 may be configured to be heated up using a laser and the adhesion promotion layer may be configured to reduce reflection of the laser light at the joining site 115. In this way, the heating efficiency of the laser may be improved. Additionally or alternatively, the adhesion promotion layer may comprise or consist of a thin metal mesh attached to the second side 112 at least at the joining site 115. Such a mesh may improve the adhesion between the carrier 110 and the cooler provided by the thermoplastic bond.

According to an example, the joining site 115 has a thickness t (compare FIG. 3) in the range of about 1 mm to about 20 mm. The lower limit of this range may also be about 3 mm, about 5 mm, about 8 mm or about 10 mm and the upper limit may also be about 18 mm, about 15 mm, or about 12 mm.

The power semiconductor module 300 may for example comprise an encapsulation encapsulating the power semiconductor die 120 (not shown in FIG. 3). The encapsulation may e.g. comprise a molded part, a plastic part, a polymer, etc. The encapsulation may be arranged on the first side 111 of the carrier 110.

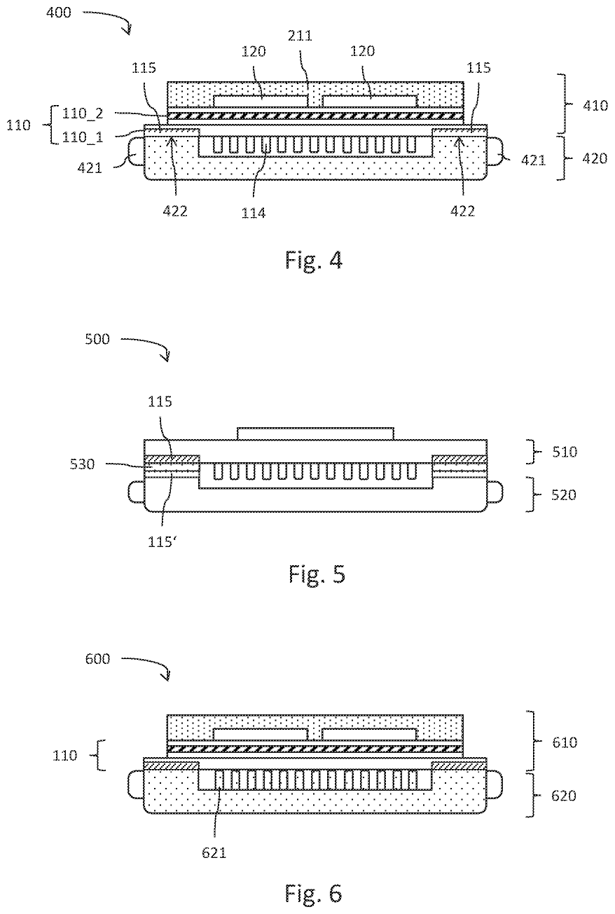

FIG. 4 shows a system 400 comprising a power semiconductor module 410 and a cooler 420 joined to the power semiconductor module 410 at the joining site 115. The power semiconductor module 410 may be similar or identical to the power semiconductor module 300. The cooler 420 may be similar or identical to the cooler 220, except for the differences described in the following.

The cooler 420 may comprise or consist of a plastic, a polymer, a mold material, a cast material, etc. (i.e. a material which is capable of forming a thermoplastic bond with the joining site 115). According to an example, the whole cooler 420 or nearly the whole cooler 420 comprises or consists of one or more of these materials. According to another example, at least the part of the cooler 420 that is in direct contact with the joining site 115 comprises or consists of one or more of these materials and another part of the cooler 420 or the rest of the cooler 420 comprises of a different material, e.g. a metal or metal alloy, in particular Al.

The power semiconductor module 410 and the cooler 420 are joined at the joining site 115 via a thermoplastic bond formed by the material of the cooler 420. The cooler 420 may comprise a burr or similar alteration close to the joining site where the material of the cooler has been molten to form the thermoplastic bond.

Since the power semiconductor module 410 and the cooler 420 are joined via the thermoplastic bond, the system 400 may be free of any further fastening elements like screws, rivets or clamps that fasten the power semiconductor module 410 to the cooler 420. Furthermore, the system 400 may be free of any sealing ring arranged at the interface between the power semiconductor module 410 and the cooler 420 because the thermoplastic bond already provides a watertight seal for this interface.

FIG. 5 shows a further system 500 comprising a power semiconductor module 510 and a cooler 520 joined to the power semiconductor module 510 via a plastic interface 530. The power semiconductor module 510 may be similar or identical to the power semiconductor module 300 or 410. The cooler 420 may be similar or identical to the cooler 220. The cooler 420 may in particular be a metal cooler.

In the system 200 shown in FIG. 2, the housing 130 is used to couple the cooler 220 to the power semiconductor module 210, wherein the housing 130 may e.g. be a molded body. In the system 500 shown in FIG. 5, the plastic interface 530 (e.g. a plastic frame or plastic ring or in general a plastic part) is coupled to the power semiconductor module 210 to the cooler 520. To this end, a first thermoplastic bond couples the plastic interface 530 to the power semiconductor module 510 and a second thermoplastic bond couples the plastic interface 530 to the cooler 520. The first thermoplastic bond may e.g. be formed by heating up the power semiconductor module 510 (in particular, the joining site 115). The second thermoplastic bond may e.g. be formed by heating up the cooler 520 (in particular, a joining site 115′). The material of the plastic interface 530 is used to form both the first and second thermoplastic bonds. The first and second thermoplastic bonds may each be formed using a heat staking process.

FIG. 6 shows a further system 600 comprising a power semiconductor module 610 and a cooler 620. The system 600 shown in FIG. 6 may for example be similar or identical to the system 400 shown in FIG. 4, except for the differences described in the following.

In the system 600 shown in FIG. 6, the carrier 110 does not necessarily comprise the cooling structures 114. Alternatively or additionally, the cooler 620 may comprise a plurality of turbulence generating structures 621. These turbulence generating structures 621 may for example be protrusion extending from the bottom of the fluid channel towards the power semiconductor module 610. The turbulence generating structures 621 may or may not be in direct contact with the carrier 110. As with the other power semiconductor modules described here, the power semiconductor module 610 may comprise a baseplate (this example is shown in FIG. 6) or the power semiconductor module 610 may be free of a baseplate (meaning that the cooler is coupled to a power electronic substrate).

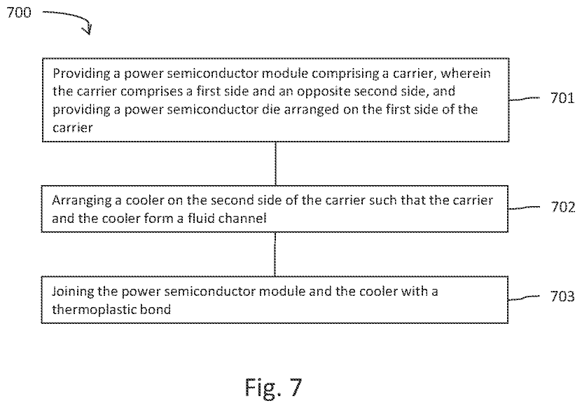

FIG. 7 is a flow chart of a method 700 for fabricating a system. The method 700 may for example be used to fabricate the system 200 shown in FIG. 2 or the system 400 shown in FIG. 4.

The method 700 comprises at 701 a process of providing a power semiconductor module comprising a carrier, wherein the carrier comprises a first side and an opposite second side, and providing a power semiconductor die arranged on the first side of the carrier. This may comprise attaching the power semiconductor die to the first side, fabricating electrical connections and/or encapsulating the power semiconductor die. The method 700 comprises at 702 a process of arranging a cooler on the second side of the carrier such that the carrier and the cooler form a fluid channel, and at 703 a process of joining the power semiconductor module and the cooler with a thermoplastic bond.

According to an example of the method 700, the power semiconductor module further comprises a housing arranged at least partially on the second side of the carrier, wherein the housing forms a joining site on the second side. Furthermore, the process 703 of joining the power semiconductor module and the cooler may comprise pressing the cooler onto the joining site of the housing and heating up the cooler (e.g. up to 250° C. or 350° C. or more) such that the housing melts at the joining site (i.e. using a heat staking process to fabricate the thermoplastic bond). When the material of the housing subsequently hardens, the thermoplastic bond is formed. In order to melt the material of the housing, the cooler may for example be placed into an oven or onto a hot plate prior to pressing the cooler onto the joining site of the power semiconductor module. In this way, overheating the power semiconductor module and/or melting solder joints of the power semiconductor module is avoided. Alternatively, in the case that overheating or melting are not an issue (e.g. due to sufficient temperature stability of the power semiconductor module) both the power semiconductor module and cooler pressed onto the joining site may be placed into the oven or onto the hot plate and heated up. Hardening of the molten material may for example be done at room temperature.

According to another example of the method 700, the cooler is or comprises a plastic part comprising a joining site. In this case, a joining site on the second side of the carrier comprises a roughened surface texture and/or a plurality of micro holes and/or a ridge and/or a furrow. The process 703 of joining the power semiconductor module and the cooler may in this case comprise using a heat staking process, wherein the power semiconductor module is heated up in order to fabricate thermoplastic bond between the power semiconductor module and the cooler. The temperature up to which the power semiconductor module may be heated up may depend on the packaging and interconnection technology used in the power semiconductor module. According to an example, the power semiconductor module does not comprise polymer or plastic parts at this point. The maximum temperature for the heat staking process may e.g. be more than 300° C., about 300° C. or about 260° C.

According to yet another example, the process 703 of joining the power semiconductor module and the cooler may comprise pressing the joining site of the cooler onto the joining site on the second side of the carrier and heating up the joining site of the second side of the carrier using a laser, such that the joining site of the cooler melts and fills the roughened surface texture and/or the micro holes (such a process may be referred to as “laser-assisted joining of plastics and metal” or “laser plastic welding”). The laser may for example be directed onto the joining site of the carrier through the material of the cooler. For this reason, the material of the cooler and the wavelength of the laser may be matched such that the material is transparent or essentially transparent for the laser (according to an example, an infrared laser may be used). Heating up the joining site on the second side of the carrier locally using a laser may prevent overheating and/or melting other parts of the power semiconductor module.

In the following, the power semiconductor module, the system and the method for fabricating a power semiconductor module are further explained using specific examples.

Example 1 is a power semiconductor module, comprising: a carrier comprising a first side and an opposite second side, a power semiconductor die arranged at the first side of the carrier, and a housing arranged at least partially on the second side of the carrier and forming a joining site for a cooler on the second side, wherein the joining site completely surrounds an inner portion of the second side of the carrier, wherein the inner portion is configured to be in direct contact with a cooling fluid within the cooler.

Example 2 is the semiconductor module of example 1, wherein the inner portion of the second side of the carrier comprises a plurality of cooling structures.

Example 3 is the semiconductor module of example 1 or 2, wherein the carrier comprises: a lid part for a fluid channel, and a power electronic substrate comprising two conductive layers separated by an insulating layer, the power electronic substrate being arranged between the power semiconductor die and the lid part.

Example 4 is the semiconductor module of one of the preceding examples, wherein the housing also at least partially covers the first side of the carrier.

Example 5 is the semiconductor module of example 4, wherein the carrier further comprises lateral sides connecting the first and second sides, and wherein the housing also at least partially covers the lateral sides.

Example 6 is the semiconductor module of one of the preceding examples, wherein the joining site has a height measured perpendicular to the second side of 3 mm or more and a thickness measured parallel to the second side of 3 mm or more.

Example 7 is a power semiconductor module, comprising: a carrier comprising a first side and an opposite second side, and a power semiconductor die arranged on the first side of the carrier, wherein a joining site for a cooler on the second side of the carrier comprises a roughened surface texture and/or a plurality of micro holes, the joining site completely surrounding an inner portion of the second side of the carrier, wherein the inner portion is configured to be in direct contact with a cooling fluid within the cooler.

Example 8 is the power semiconductor module of example 7, wherein the inner portion of the second side of the carrier comprises a plurality of cooling structures.

Example 9 is the power semiconductor module of example 7 or 8, wherein the carrier comprises an adhesion promotion layer at least in the joining site on the second side, wherein the adhesion promotion layer has a different reflective factor than the rest of the second side.

Example 10 is the power semiconductor module of one of examples 7 to 9, wherein the roughened surface texture and/or the micro holes are structures fabricated using a laser or an etching process.

Example 11 is the power semiconductor module of one of examples 7 to 10, wherein the joining site has a thickness measured parallel to the second side of 3 mm or more.

Example 12 is a system, comprising: a power semiconductor module, comprising: a carrier comprising a first side and an opposite second side, and a power semiconductor die arranged on the first side of the carrier; and a cooler arranged on the second side of the carrier, such that the carrier and the cooler form a fluid channel, wherein the power semiconductor module and the cooler are joined by a thermoplastic bond.

Example 13 is the system of example 12, wherein the power semiconductor module further comprises a housing arranged at least on the second side of the carrier, the housing forming a joining site on the second side, wherein the joining site completely surrounds an inner portion of the second side of the carrier, wherein the inner portion is configured to be in direct contact with a cooling fluid within the cooler, and wherein the cooler is or comprises an aluminum part and the thermoplastic bond is formed by the joining site.

Example 14 is the system of example 12, wherein a joining site on the second side of the carrier comprises a roughened surface texture and/or a plurality of micro holes, the joining site completely surrounding an inner portion of the second side of the carrier, wherein the inner portion is configured to be in direct contact with a cooling fluid within the cooler, and wherein the cooler is or comprises a plastic part comprising a joining site, wherein the thermoplastic bond is formed by the joining site of the plastic part.

Example 15 is a method for fabricating a system, the method comprising: providing a power semiconductor module, comprising: a carrier comprising a first side and an opposite second side, and a power semiconductor die arranged on the first side of the carrier; arranging a cooler on the second side of the carrier such that the carrier and the cooler form a fluid channel; and joining the power semiconductor module and the cooler with a thermoplastic bond.

Example 16 is the method of example 15, wherein the fluid channel is sealed by the thermoplastic bond.

Example 17 is the method of example 15 or 16, wherein the power semiconductor module further comprises a housing arranged at least partially on the second side of the carrier, the housing forming a joining site on the second side, wherein the joining site completely surrounds an inner portion of the second side of the carrier, wherein the inner portion is configured to be in direct contact with a cooling fluid within the cooler, and wherein joining the power semiconductor module and the cooler comprises pressing the cooler onto the joining site of the housing and heating up the cooler such that the housing melts at the joining site.

Example 18 is the method of example 15 or 16, wherein the cooler is or comprises a plastic part comprising a joining site, wherein a joining site on the second side of the carrier comprises a roughened surface texture and/or a plurality of micro holes, the joining site completely surrounding an inner portion of the second side of the carrier, wherein the inner portion is configured to be in direct contact with a cooling fluid within the cooler, and wherein joining the power semiconductor module and the cooler comprises pressing the joining site of the cooler onto the joining site on the second side of the carrier and heating up the joining site of the second side of the carrier using a laser or a heat staking process, such that the joining site of the cooler melts and fills the roughened surface texture and/or the micro holes.

Example 19 is an apparatus comprising means for performing the method according to anyone of examples 15 to 18.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power semiconductor module, comprising:
a carrier comprising a first side and an opposite second side;
a power semiconductor die arranged at the first side of the carrier; and
a housing arranged at least partially on the second side of the carrier and forming a joining site for a cooler on the second side,
wherein the joining site completely surrounds an inner portion of the second side of the carrier,
wherein the inner portion is configured to be in direct contact with a cooling fluid within the cooler.

2. The semiconductor module of claim 1, wherein the inner portion of the second side of the carrier comprises a plurality of cooling structures.

3. The semiconductor module of claim 1, wherein the carrier comprises:
a lid part for a fluid channel; and
a power electronic substrate comprising two conductive layers separated by an insulating layer, the power electronic substrate being arranged between the power semiconductor die and the lid part.

4. The semiconductor module of claim 1, wherein the housing at least partially covers the first side of the carrier.

5. The semiconductor module of claim 4, wherein the carrier further comprises lateral sides connecting the first and second sides, and wherein the housing at least partially covers the lateral sides.

6. The semiconductor module of claim 1, wherein the joining site has a height measured perpendicular to the second side of 3 mm or more and a thickness measured parallel to the second side of 3 mm or more.

7. A power semiconductor module, comprising:
a carrier comprising a first side and an opposite second side; and
a power semiconductor die arranged on the first side of the carrier,
wherein a joining site for a cooler on the second side of the carrier comprises a roughened surface texture and/or a plurality of micro holes, the joining site completely surrounding an inner portion of the second side of the carrier,
wherein the inner portion is configured to be in direct contact with a cooling fluid within the cooler.

8. The power semiconductor module of claim 7, wherein the inner portion of the second side of the carrier comprises a plurality of cooling structures.

9. The power semiconductor module of claim 7, wherein the carrier comprises an adhesion promotion layer at least in the joining site on the second side, and wherein the adhesion promotion layer has a different reflective factor than the rest of the second side.

10. The power semiconductor module of claim 7, wherein the roughened surface texture and/or the micro holes are structures fabricated using a laser or an etching process.

11. The power semiconductor module of claim 7, wherein the joining site has a thickness measured parallel to the second side of 3 mm or more.

12. A system, comprising:
a power semiconductor module comprising a carrier comprising a first side and an opposite second side, and a power semiconductor die arranged on the first side of the carrier; and
a cooler arranged on the second side of the carrier, such that the carrier and the cooler form a fluid channel,
wherein the power semiconductor module and the cooler are joined by a thermoplastic bond.

13. The system of claim 12, wherein the power semiconductor module further comprises a housing arranged at least on the second side of the carrier, the housing forming a joining site on the second side, wherein the joining site completely surrounds an inner portion of the second side of the carrier, wherein the inner portion is configured to be in direct contact with a cooling fluid within the cooler, and wherein the cooler is or comprises an aluminum part and the thermoplastic bond is formed by the joining site.

14. The system of claim 12, wherein a joining site on the second side of the carrier comprises a roughened surface texture and/or a plurality of micro holes, the joining site completely surrounding an inner portion of the second side of the carrier, wherein the inner portion is configured to be in direct contact with a cooling fluid within the cooler, wherein the cooler is or comprises a plastic part comprising a joining site, and wherein the thermoplastic bond is formed by the joining site of the plastic part.

15. A method for fabricating a system, the method comprising:
providing a power semiconductor module comprising a carrier comprising a first side and an opposite second side, and a power semiconductor die arranged on the first side of the carrier;
arranging a cooler on the second side of the carrier such that the carrier and the cooler form a fluid channel; and
joining the power semiconductor module and the cooler with a thermoplastic bond.

16. The method of claim 15, wherein the fluid channel is sealed by the thermoplastic bond.

17. The method of claim 15, wherein the power semiconductor module further comprises a housing arranged at least partially on the second side of the carrier, the housing forming a joining site on the second side, wherein the joining site completely surrounds an inner portion of the second side of the carrier, wherein the inner portion is configured to be in direct contact with a cooling fluid within the cooler, and wherein joining the power semiconductor module and the cooler comprises pressing the cooler onto the joining site of the housing and heating up the cooler such that the housing melts at the joining site.

18. The method of claim 15, wherein the cooler is or comprises a plastic part comprising a joining site, wherein a joining site on the second side of the carrier comprises a roughened surface texture and/or a plurality of micro holes, the joining site completely surrounding an inner portion of the second side of the carrier, wherein the inner portion is configured to be in direct contact with a cooling fluid within the cooler, and wherein joining the power semiconductor module and the cooler comprises pressing the joining site of the cooler onto the joining site on the second side of the carrier and heating up the joining site of the second side of the carrier using a laser or a heat staking process, such that the joining site of the cooler melts and fills the roughened surface texture and/or the micro holes.
